(19) United States
(12) Patent Application Publication
(10) Pub. No.: US 2002/0081524 A1
(43) Pub. Date: Jun. 27, 2002

(54) Chemical amplifying type positive resist composition

(76) Inventors: Yasunori Uetani, Osaka (JP); Kazuhiko Hashimoto, Tsukuba-shi (JP); Hiroaki Fujishima, Osaka (JP)

Correspondence Address: BIRCH STEWART KOLASCH & BIRCH, PO BOX 747, FALLS CHURCH, VA, 22040-0747, US

(21) Appl. No.: 10/022,908

(22) Filed: Dec. 20, 2001

(30) Foreign Application Priority Data
Dec. 22, 2000 (JP) 2000-390708

(51) Int. Cl. G03F 7/038

(52) U.S. Cl. 430/270.1; 430/326

(57) ABSTRACT

A chemical amplifying type positive resist composition is provided which is excellent in transmittance for the wavelength of F₂ excimer light. Therefore, it is suitable for fine processing of a semiconductor using F₂ excimer laser; and comprises an acid generating agent and a resin which contains a polymerization unit derived from an alicyclic hydrocarbon having a polymerizable carbon-carbon double bond in the ring and a polymerization unit derived from (meth)acrylonitrile, and which itself is insoluble or slightly soluble in an alkali but becomes alkali-soluble due to the action of an acid.

### BACKGROUND OF THE INVENTION

1. Field of the Invention

The present invention relates to a chemical amplifying type positive resist composition used in the fine processing of a semiconductor.

2. Description of Related Art

In the fine processing of semiconductor, a lithography process using a resist composition is usually adopted. In lithography, it is theoretically possible to increase resolution higher when exposure wavelength is shorter as represented by the Rayleigh diffraction limit formula. As the lithography exposure light source used in production of semiconductors, there have been used g ray having a wavelength of 436 nm, i ray having a wavelength of 365 nm, KrF excimer laser having a wavelength of 248nm and ArF excimer laser having a wavelength of 193 nm, the wavelength becoming shorter year by year. F₂ excimer laser having a wavelength of 157 nm is promising as the exposure light source of the next generation. Further, as the exposure light source of the subsequent generation, extreme ultraviolet (EUV) ray having a wavelength of 13 nm is considered.

Since a lens used in an ArF excimer laser exposure machine and exposure machine manifesting shorter wavelengths has a shorter life as compared with the life of those used in conventional exposure light sources, it is desirable that the time of exposure to ArF excimer laser light is as short as possible. For this purpose, the sensitivity of a resist is required to be enhanced, leading to use of a so-called chemical amplifying type resist containing a resin having a group which is decomposed by the catalytic action of an acid generated by exposure.

It is known that, as a resin used in a resist for ArF excimer laser exposure, those having no aromatic ring, for securing the transmittance of a resist and having an alicyclic ring instead of an aromatic ring, for obtaining dry etching resistance are advantageous. As such a resin, there are reported, for example, copolymers of (meth)acrylates having an alicyclic ring, copolymers of (meth)acrylates, unsaturated alicyclic hydrocarbons such as norbornene, tricyclodecene and tetracyclododecene, and maleic anhydride, copolymers of alicyclic unsaturated carboxylates such as norbornenecarboxylates, tricyclodecenecarboxylates and tetracyclododecenecarboxylates, and maleic anhydride, further, those obtained by copolymerizing these copolymers with (meth)acrylates.

However, a resin used in a resist for ArF excimer laser exposure conventionally reported manifests poor transmission of F₂ excimer laser light (wavelength: 157 nm) and is not suitable as a resin for F₂ excimer laser exposure resist.

An object of the present invention is to provide a positive resist composition of chemical amplifying type manifesting high transmission of F₂ excimer laser (157 nm).

The present inventors have intensively studied and resultantly found that, in a positive resist composition of chemical amplifying type containing an acid generating agent and a resin component which itself is insoluble or slightly soluble in an alkali but becomes alkali-soluble due to the action of an acid, if a resin containing a polymerization unit of an alicyclic hydrocarbon having a polymerizable carbon-carbon double bond in the ring and a polymerization unit derived from (meth)acrylonitrile is used as the resin component, transmittance of F₂ excimer laser (157 nm) increases. The present invention was thus completed.

### SUMMARY OF THE INVENTION

The present invention provides a chemical amplifying type positive resist composition for F₂ excimer laser comprising an acid generating agent and a resin which contains a polymerization unit derived from an alicyclic hydrocarbon having a polymerizable carbon-carbon double bond in the ring and a polymerization unit derived from (meth)acrylonitrile, and which itself is insoluble or slightly soluble in an alkali but becomes alkali-soluble due to the action of an acid.

### DETAILED DESCRIPTION OF EMBODIMENTS

The present invention is characteristic in that a resin, one component of a resist, contains a polymerization unit derived from an alicyclic hydrocarbon having a polymerizable carbon-carbon double bond in the ring and a polymerization unit derived from (meth)acrylonitrile. By this fact, both high dry etching resistance and high transmittance of excimer laser at a wavelength of 157 nm can be obtained.

The resin defined in the present invention is itself insoluble or slightly soluble in an alkali but become alkali-soluble due to the action of an acid, for manifesting a function as a chemical amplifying positive resist. For this, the resin is required to have an alkali-soluble group protected by a group decomposable due to the action of an acid. The alkali-soluble group protected by a group decomposable due to the action of an acid may be contained in a polymerization unit derived from an alicyclic hydrocarbon having a polymerizable carbon-carbon double bond in the ring, or may be contained in other polymerization unit than it.

Examples of the polymerization unit derived from an alicyclic hydrocarbon having a polymerizable carbon-carbon double bond in the ring include those of the following general formulae (Ia) to (Ic):

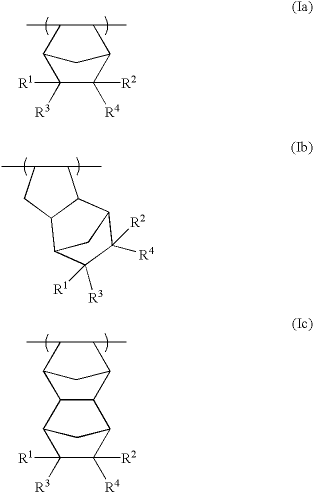

wherein, R¹, R², R³ and R⁴ each independently represent a hydrogen atom, an acid-unstable group which is decomposed in the presence of an acid to become alkali-soluble, or an alkyl group in which a part of hydrogen atoms may be substituted by a hydroxyl group and fluorine atom.

Specific examples of the resin, which contains a polymerization unit derived from an alicyclic hydrocarbon having a polymerizable carbon-carbon double bond in the ring, and a polymerization unit derived from (meth)acrylonitrile, and which itself is insoluble or slightly soluble in an alkali but becomes alkali-soluble due to the action of an acid, include copolymers containing at least one of combinations of polymerization units of the following formulae (II) to (IX):

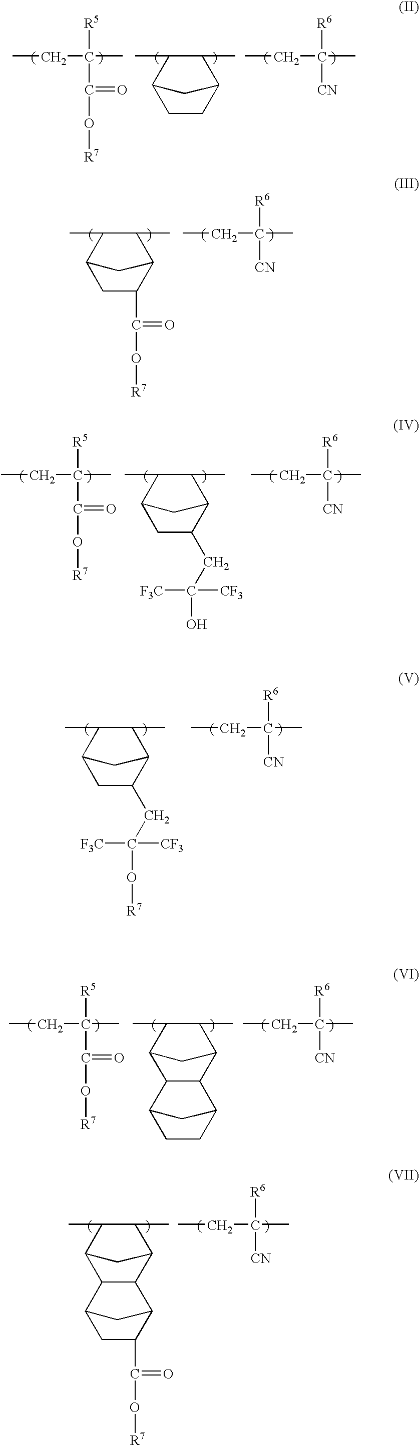

wherein, R⁵ and R⁶ represent hydrogen or a methyl group, and R⁷ represents an acid-unstable group.

The acid-unstable group represented by R⁷ may be selected from known various protective groups. Examples thereof include groups in which quaternary carbon bonds to an oxygen atom such as tert-butyl, tert-butoxycarbonyl and tert-butoxycarbonylmethyl; groups of acetal type such as tetrahydro-2-pyranyl, tetrahydro-2-furyl, 1-ethoxyethyl, 1-(2-methylpropoxy)ethyl, 1-(2-methoxyethoxy)ethyl, 1-(2-acetoxyethoxy)ethyl, 1-[2-(1-adamantyloxy)ethoxy]ethyl and 1-[2-(1-adamantanecarbonyloxy)ethoxy]ethyl; residues of non-aromatic cyclic compounds such as 3-oxocyclohexyl, 4-methyltetrahydro-2-pyron-4-yl (derived from mevaloniclactone), 2-alkyl-2-adamantyl and 1-(1-adamantyl)-1-alkylalkyl; and the like. These groups are substituted for hydrogen of an alkali-soluble group. These protective groups can be introduced into a resin by performing a known protective group introduction reaction or conducting copolymerization using, as one monomer, an unsaturated compound having such a group.

The resin defined in the present invention can be produced by a known radical polymerization. The radical polymerization can be carried out, for example, by mixing a monomer deriving the above polymerization unit and a radical generator in the presence or absence of a solvent, and heating. The polymer thus obtained can be purified, for example, by precipitating the polymer by adding a suitable solvent.

Molecular weight of the resin usable in the present invention is not particularly limited. However, for obtaining a resist composition having good resist performances such as resolution and sensitivity, it is generally preferable that the weight average molecular weight measured by gel permeation chromatography in terms of polystyrene is 800 to 100,000, more preferable 1,000 to 20,000.

In general, the resin used in the present invention preferably contains 20 to 70 mol % of a polymerization unit derived from an alicyclic hydrocarbon having a polymerizable carbon-carbon double bond in the ring, and preferably contains 20 to 70 mol % of a polymerization unit having a group decomposable due to the action of an acid though it varies depending on the kind of radiation for patterning exposure, the kind of a group which is decomposed due to the action of an acid, and the like. Further, this resin can contain also other polymerization units, for example, norbornenecarboxylates having an ester portion not decomposable due to the action of an acid, (meth)acrylic acid, (meth)acrylates not decomposable due to the action of an acid, and the like, in an amount which does not impair the effect of the invention.

The acid generating agent used in the present invention is a substance which is decomposed to generate an acid by applying a radiation such as a light, an electron beam or the like on the substance itself or on a resist composition containing the substance. The acid generated from the acid generating agent acts on said resin resulting in cleavage of the group cleavable by the action of an acid existing in the resin.

Such acid generating agents, for example, include other onium salt compounds, organno-halogen compound, sulfone compounds, sulfonate compounds, and the like.

Specific examples thereof include: diphenyliodonium trifluoromethanesulfonate, 4-methoxyphenylphenyliodonium hexafluoroantimonate, 4-mthoxyphenylphenyliodonium trifluoromethanesulfonate, bis(4-tert-butylphenyl)iodonium tetrafluoroborate, bis(4-tert-butylphenyl)iodonium hexafluorophosphate, bis(4-tert-butylphenyl)iodonium hexafluoroantimonate, bis(4-tert-butylphenyl)iodonium trifluoromethanesulfonate, triphenylsulfonium hexafluorophosphate, triphenylsulfonium hexafluoroantimonate, triphenylsulfonium trifluoromethanesulfonate, 4-methoxyphenyldiphenylsulfonium hexafluoroantimonate, 4-methoxyphenyldiphenylsulfonium trifluoromethanesulfonate, p-tolyldiphenylsulfonium trifluoromethanesulfonate, p-tolyldiphenylsulfonium perfluorobutanesulfonate, p-tolyldiphenylsulfonium perfluorooctanesulfonate, 2,4,6-trimethylphenyldiphenylsulfonium trifluoromethanesulfonate, 4-tert-butylphenyldiphenylsulfonium trifluoromethanesulfonate, 4-phenylthiophenyldiphenylsulfonium hexafluorophosphate, 4-phenylthiophenyldiphenylsulfonium hexafluoroantimonate, 1-(2-naphthoylmethyl)thiolanium hexafluoroantimonate, 1-(2-naphthoylmethyl)thiolanium trifluoromethanesulfonate, 4-hydroxy-1-naphthyldimethylsulfonium hexafluoroantimonate, 4-hydroxy-1-naphthyldimethylsulfonium trifluoromethanesulfonate, 2-methyl-4,6-bis(trichloromethyl)-1,3,5-triazine, 2,4,6-tris(trichloromethyl)-1,3,5-triazine, 2-phenyl-4,6-bis(trichloromethyl)-1,3,5-triazine, 2-(4-chlorophenyl)-4,6-bis(trichloromethyl)-1,3,5-triazine, 2-(4-methoxyphenyl)-4,6-bis(trichloromethyl)-1,3,5-triazine, 2-(4-methoxy-1-naphthyl)-4,6-bis(trichloromethyl)-1,3,5-triazine, 2-(benzo[d][1,3]dioxolane-5-yl)-4,6-bis(trichloromethyl)-1,3,5-triazine, 2-(4-methoxystyryl)-4,6-bis(trichloromethyl)-1,3,5-triazine, 2-(3,4,5-trimethoxystyryl)-4,6-bis(trichloromethyl)-1,3,5-triazine, 2-(3,4-dimethoxystyryl)-4,6-bis(trichloromethyl)-1,3,5-triazine, 2-(2,4-dimethoxystyryl)-4,6-bis(trichloromethyl)-1,3,5-triazine, 2-(2-methoxystyryl)-4,6-bis(trichloromethyl)-1,3,5-triazine, 2-(4-butoxystyryl)-4,6-bis(trichloromethyl)-1,3,5-triazine, 2-(4-pentyloxystyryl)-4,6-bis(trichloromethyl)-1,3,5-triazine, 1-benzoyl-1-phenylmethyl p-toluenesulfonate (so-called benzointosylate), 2-benzoyl-2-hydroxy-2-phenylethyl p-toluenesulfonate (so-called α-methylolbenzointosylate), 1,2,3-benzenetriyl trimethanesulfonate, 2,6-dinitrobenzyl p-toluenesulfonate, 2-nitrobenzyl p-toluenesulfonate, 4-nitrobenzyl p-toluenesulfonate, diphenyl disulfone, di-p-tolyl disulfone, bis(phenylsulfonyl)diazomethane, bis(4-chlorophenylsulfonyl)diazomethane, bis(p-tolylsulfonyl)diazomethane, bis(4-tert-butylphenylsulfonyl)diazomethane, bis(2,4-xylylsulfonyl)diazomethane, bis(cyclohexylsulfonyl)diazomethane, (benzoyl)(phenylsulfonyl)diazomethane, N-(phenylsulfonyloxy)succinimide, N-(trifluoromethylsulfonyloxy)succinimide, N-(trifluoromethylsulfonyloxy)phthalimide, N-(trifluoromethylsulfonyloxy)-5-norbornene-2,3-dicarboxyimide, N-(trifluoromethylsulfonyloxy)naphthalimide, N-(10-camphorsulfonyloxy)naphthalimide, and the like.

It is also known that, generally in a chemical amplifying type positive resist composition, performance deterioration due to the deactivation of an acid associated with leaving after exposure can be reduced by adding basic compounds, especially basic nitrogen-containing organic compounds such as amines as quenchers. It is also preferable in the present invention that such basic compounds are added. Concrete examples of the basic compounds to be used as quenchers include the ones represented by the following formulae:

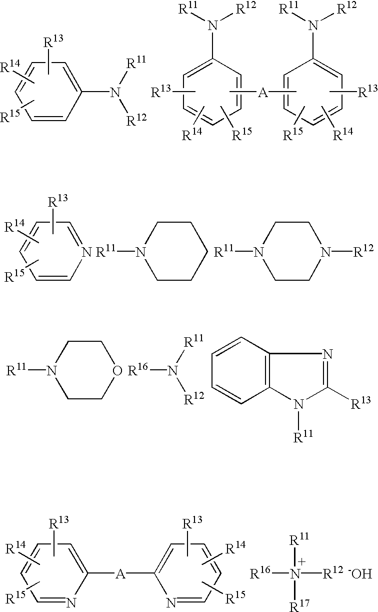

wherein R¹¹, R¹² and R¹⁷ represent, independently each other, hydrogen, cycloalkyl, aryl or alkyl which may be optionally substituted with a hydroxyl, amino which may be optionally substituted with alkyl having 1 to 6 carbon atoms, or alkoxy having 1 to 6 carbon atoms; R¹³, R¹⁴ and R¹⁵, which are same or different from each other, represent hydrogen, cycloalkyl, aryl, alkoxy or alkyl which may be optionally substituted with a hydroxyl, amino which may be optionally substituted with alkyl having 1 to 6 carbon atoms, or alkoxy having 1 to 6 carbon atoms; R¹⁶ represents cycloalkyl or alkyl which may be optionally substituted with a hydroxyl, amino which may be optionally substituted with alkyl having 1 to 6 carbon atoms, or alkoxy having 1 to 6 carbon atoms; A represents alkylene, carbonyl, imino, sulfide or disulfide. The alkyl represented by R¹¹ to R¹⁷ and alkoxy represented by R¹³ to R¹⁵ may have about 1 to 6 carbon atoms. The cycloalkyl represented by R¹¹ to R¹⁷ may have about 5 to 10 carbon atoms and the aryl represented by R¹¹ to R¹⁵ and R¹⁷ may have about 6 to 10 carbon atoms. The alkylene represented by A may have about 1 to 6 carbon atoms and may be straight-chained or branched.

The resist composition of the present invention preferably contains the resin in an amount of 80 to 99.9% by weight, and the acid generating agent in an amount of 0.1 to 20% by weight based on the total solid component weight of the resist composition. When a basic compound is used as a quencher, it is preferably contained in an amount in the range of 0.001 to 0.1% by weight based on the total solid component weight of the resist composition. The composition may also contain, if required, a small amount of various additives such as sensitizers, dissolution inhibitors, resins other than the above resin, surfactants, stabilizers, and dyes so far as the objects of the present invention is not harmed.

The resist composition of the present invention generally becomes a resist solution in the state in which the above-described components are dissolved in a solvent to be applied on a substrate such as a silicon wafer. The solvent herein used may be one which dissolves each component, has an appropriate drying rate, and provides a uniform and smooth coating after evaporation of the solvent, and can be one which is generally used in this field.

Examples thereof include glycol ether esters such as ethylcellosolve acetate, methylcellosolve acetate, and propylene glycol monomethyl ether acetate; esters such as ethyl lactate, butyl acetate, amyl acetate, and ethyl pyruvate; ketones such as acetone, methyl isobutyl ketone, 2-heptanone, and cyclohexanone; and cyclic esters such as γ-butyrolactone. These solvents can be used alone or in combination of two or more thereof.

The resist film applied on a substrate, and dried is subjected to an exposure treatment for patterning. Then, after a heat-treatment for promoting a protecting deblocking reaction, development by an alkali developer is conducted. The alkali developer herein used can be various kinds of alkaline aqueous solutions used in this field. In general, an aqueous solution of tetramethylammoniumhydroxide or (2-hydroxyethyl)trimethylammoniumhydroxide (so-called colline) is often used.

The present invention will be described in more detail by way of examples, which should not be construed as limiting the scope of the present invention. All parts in examples are by weight unless otherwise stated. The weight-average molecular weight is a value determined from gel permeation chromatography using polystyrene as a reference standard.

### Monomer Synthesis Example 1

### Production of tert-butyl 5-norbornene-2-carboxylate

A Diels-Alder reaction with 86.0g (0.67mol) of tert-butyl acrylate was conducted at room temperature using a large excess amount of fresh cyclopentadiene obtained by distillation. The reaction product was distilled at the boiling point of 80° C. under reduced pressure to obtain tert-butyl 5-norbornene-2-carboxylate at a yield in terms of tert-butylacrylate of 90%. The chemical reaction formula for this example is as described below.

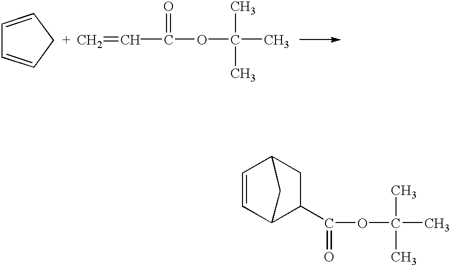

### Resin Synthesis Example 1

### Production of tert-butyl 5-norbornene-2-carboxylate/maleic anhydride copolymer

45.0 g of 1,4-dioxane was added to 15.0 g (77.2 mmol) of tert-butyl 5-norbornene-2-carboxylate obtained in Monomer Synthesis Example 1 and 7.57 g (77.2 mmol) of maleic anhydride to prepare a solution, and the solution was heated under a nitrogen atmosphere to 80° C. To this was added 0.25 g of 2,2′-azobisisobutyronitrile as an initiator, and the mixture was stirred for 48 hours under the same condition. Then, the reaction mass was mixed with a large amount of n-heptane to precipitate a resin, and the resin was filtrated. This wet cake was then dissolved in 1,4-dioxane, and the mixture was mixed with a large amount of n-heptane to precipitate a resin, and the resin was filtrated. This operation from dissolution to re-precipitation was repeated twice for purification, to obtain a copolymer having a weight-average molecular weight of 4750 and a degree of dispersion of 1.6. This is referred to as Resin X.

### Resin Synthesis Example 2

### Production of tert-butyl 5-norbornene-2-carboxylate/methacrylonitrile copolymer

80 g of methyl isobutyl ketone was added to 61.9 g of tert-butyl 5-norbornene-2-carboxylate to prepare a solution. To this was added azobisisobutyronitrile as an initiator in an amount of 7.5 mol % based on tert-butyl 5-norbornene-2-carboxylate, and the resultant mixture was heated to 60° C. Into this was added dropwise a 50 wt % solution of 10.7 g of methacrylonitrile (molar ratio: tert-butyl 5-norbornene-2-carboxylate/methacrylonitrile=2/1) in methyl isobutyl ketone over 8 hours. Then, the reaction solution was concentrated under reduced pressure to remove components having a lower boiling point. Further, the concentrated residue was dissolved in methyl isobutyl ketone, and the solution was again concentrated under reduced pressured. This operation was repeated three times for purification. As a result, a copolymer having a weight-average molecular weight of about 1600 and a degree of dispersion of 1.1 was obtained. This copolymer is referred to as Resin A1.

200 mg of Resin A1 and 20 mg of acetylacetonechromium were dissolved in 0.7 ml of deuterochloroform, then, the solution was filtrated through glass wool to prepare an NMR sample. ¹³C-NMR of this sample was measured using an nuclear magnetic resonance apparatus type GX 270 manufactured by JEOL Ltd. (coupling method at inversion gate, frequency 67.7 MHz). The copolymerization ratio calculated from the integral intensity ratio of signal was tert-butyl 5-norbornene-2-carboxylate/methacrylonitrile=23/77.

### EXAMPLE

and

### Comparative Example

A resin was dissolved in propylene glycol monomethyl ether acetate, and the solution was filtrated through a fluorine resin filter having a pore diameter of 0.2 μm to prepare a resin solution.

The resin solution prepared previously was applied on a magnesium fluoride wafer to give a film having thickness after drying of 0.1 μm, and pre-baked on a direct hot plate under conditions of 110° C. for 60 seconds, to form a resist film. The transmittance of thus formed resin film at a wavelength of 157 nm was measured using a transmittance measuring function of a simple type F₂ excimer laser exposure machine [“VUVES-4500” manufactured from Litho Tech Japan Corporation].

As a result, the transmittance of Resin X1 was 26% while the transmittance of Resin A1 was 53%.

The resist composition of the present invention is excellent in transmittance for the wavelength of F₂ excimer laser light. Therefore, it is suitable for fine processing of a semiconductor using F₂ excimer laser.

We claim:

1. A chemical amplifying type positive resist composition comprising an acid generating agent and a resin which contains a polymerization unit derived from an alicyclic hydrocarbon having a polymerizable carbon-carbon double bond in the ring and a polymerization unit derived from (meth)acrylonitrile, and which itself is insoluble or slightly soluble in an alkali but becomes alkali-soluble due to the action of an acid.

2. The chemical amplifying type positive resist composition according to claim 1, wherein the polymerization unit derived from an alicyclic hydrocarbon is at least one selected from the group consisting of those represented by the following general formula (Ia), (Ib) or (Ic): 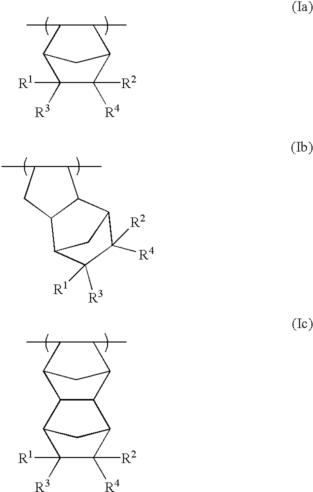
wherein, R¹, R², R³ and R⁴ each independently represent a hydrogen atom, an acid-unstable group which is decomposed in the presence of an acid to become alkali-soluble, or an alkyl group in which a part of hydrogen atoms may be substituted by a hydroxyl group and fluorine atom.

3. The chemical amplifying type positive resist composition according to claim 1, wherein the resin contains 20 to 70 mol % of a polymerization unit derived from an alicyclic hydrocarbon having a polymerizable carbon-carbon double bond in the ring.
